(19) United States
(12) Patent Application Publication
(10) Pub. No.: US 2011/0269510 A1
(43) Pub. Date: Nov. 3, 2011

(54) APPARATUS AND METHOD FOR PREVENTING TRANSMISSION DEGRADATION IN WIRELESS COMMUNICATION SYSTEM

(75) Inventor: Hun-Hee Noh, Suwon-si (KR)

(73) Assignee: SAMSUNG ELECTRONICS CO., LTD., Suwon-si (KR)

(21) Appl. No.: 13/100,187

(22) Filed: May 3, 2011

(30) Foreign Application Priority Data
May 3, 2010 (KR) 10-2010-0041385

(51) Int. Cl. H04W 52/52; H03F 1/08

(52) U.S. Cl. 455/571; 330/144

(57) ABSTRACT

An apparatus and a method for preventing transmission degradation in a mobile terminal. The apparatus includes an antenna, a Power Amplifier Module (PAM), and a matching module. The PAM amplifies power of a transmission signal. A matching module is located between the antenna and the PAM, to match impedance of a signal whose power is amplified by the PAM using a matching value determined depending on a supplied power magnitude of the PAM.

### CROSS-REFERENCE TO RELATED APPLICATION(S) AND CLAIM OF PRIORITY

This application is related to and claims priority under 35 U.S.C. §119(a) of a Korean patent application filed in the Korean Intellectual Property Office on May 3, 2010 and assigned Serial No. 10-2010-0041385, the entire disclosure of which is hereby incorporated by reference.

### TECHNICAL FIELD OF THE INVENTION

The present invention relates to an apparatus and a method for preventing transmission degradation in a wireless communication system. More particularly, the present invention relates to an apparatus and a method for minimizing current consumption at a transmission end and reducing transmission performance degradation caused by unstable power supply in a wireless communication system.

### BACKGROUND OF THE INVENTION

A transmission end of a wireless communication system generates constant transmission power using a Power Amplifier Module (PAM).

A PAM of a mobile terminal is designed to normally operate in a predetermined voltage range. For example, the PAM of the mobile terminal is designed to normally operate in a voltage range of 3.2V-4.2V.

When an operation voltage of the PAM is set to a minimum voltage of a voltage range, the PAM cannot secure a margin. Here, the voltage range denotes a range of a voltage in which the mobile terminal may normally operate.

In contrast, when the operation voltage of the PAM is set lower than the voltage range, performance degradation occurs in the PAM.

### SUMMARY OF THE INVENTION

To address the above-discussed deficiencies of the prior art, it is a primary aspect of the present invention to provide an apparatus and a method for minimizing current consumption of a transmission end in a wireless communication system.

Another aspect of the present invention is to provide an apparatus and a method for reducing transmission performance degradation caused by an unstable power supply in a wireless communication system.

Still another aspect of the present invention is to provide an apparatus and a method for minimizing current consumption of a transmission end when a power supply is stable in a wireless communication system.

In accordance with one aspect of the present invention, an apparatus operable to prevent transmission degradation in a mobile terminal is provided. The apparatus includes an antenna and a Power Amplifier Module (PAM) configured to amplify a power of a transmission signal. The apparatus also includes a matching module located between the antenna and the PAM, and configured to match an impedance of a signal whose power is amplified by the PAM using a matching value determined based on a supplied power magnitude of the PAM.

In accordance with another aspect of the present invention, a method for preventing transmission degradation in a mobile terminal is provided. The method includes determining a magnitude of supplied power of a Power Amplifier Module (PAM). The method also includes determining a matching value using the magnitude of the supplied power of the PAM. The method further includes matching an impedance of a signal whose power is amplified by the PAM using the matching, value.

Other aspects, advantages and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a mobile terminal according to an embodiment of the present invention;

FIG. 2 illustrates a procedure for changing a matching value based on supplied power in a mobile terminal according to an embodiment of the present invention; and

FIG. 3 illustrates matching values based on supplied power of a PAM according to an embodiment of the present invention.

Throughout the drawings, like reference numerals will be understood to refer to like parts, components and structures.

### DETAILED DESCRIPTION OF THE INVENTION

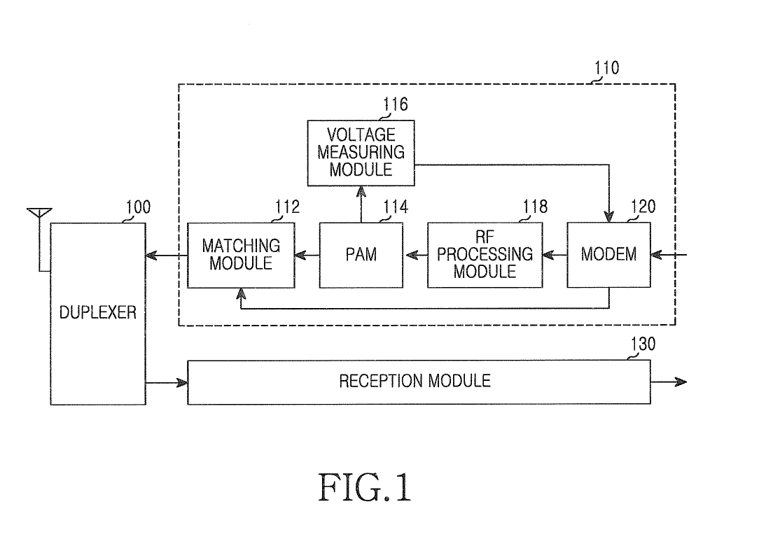

FIGS. 1 through 3, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless communication system. Embodiments of the present invention will be described herein below with reference to the accompanying drawings. In the following description, well-known functions or constructions are not described in detail since they would obscure the invention in unnecessary detail. Terms described below, which are defined considering functions in the present invention, can be different depending on user and operator's intention or practice. Therefore, the terms should be defined on the basis of the disclosure throughout this specification.

Exemplary embodiments of the present invention provide a technology for minimizing current consumption at a transmission end and reducing transmission performance degradation caused by unstable power supply in a wireless communication system.

Hereinafter, a technology for reducing current consumption when power supply is stable and reducing transmission performance degradation when power supply is unstable in a mobile terminal is described. Here, the mobile terminal includes a Personal Computer (PC) that can perform wireless communication, a wireless information communication apparatus such as a mobile communication terminal, a Personal Digital Assistant (PDA), a smart phone, an International Mobile Telecommunication-2000 (IMT-2000) terminal, a Wideband Code Division Multiple Access (WCDMA) terminal, a Universal Mobile Telecommunication Service (UMTS) terminal, and the like.

The mobile terminal is configured as illustrated in FIG. 1 to minimize current consumption when power supply is stable and to reduce transmission performance degradation caused by unstable power supply.

FIG. 1 is a block diagram illustrating a mobile terminal according to an embodiment of the present invention.

As illustrated in FIG. 1, the mobile terminal includes a duplexer 100, a transmission module 110, and a reception module 130.

The duplexer 100 is connected to an antenna and configured to separate signals of the transmission module 110 and the reception module 130. For example, when the transmission module 110 and the reception module 130 use one antenna, the duplexer 100 provides a signal received via the antenna to the reception module 130, and transmits a signal provided from the transmission module 110 via the antenna according to a duplexing scheme.

The transmission module 110 includes a matching module 112, a Power Amplifier Module (PAM) 114, a voltage measuring module 116, a Radio Frequency (RF) processing module 118, and a modem 120.

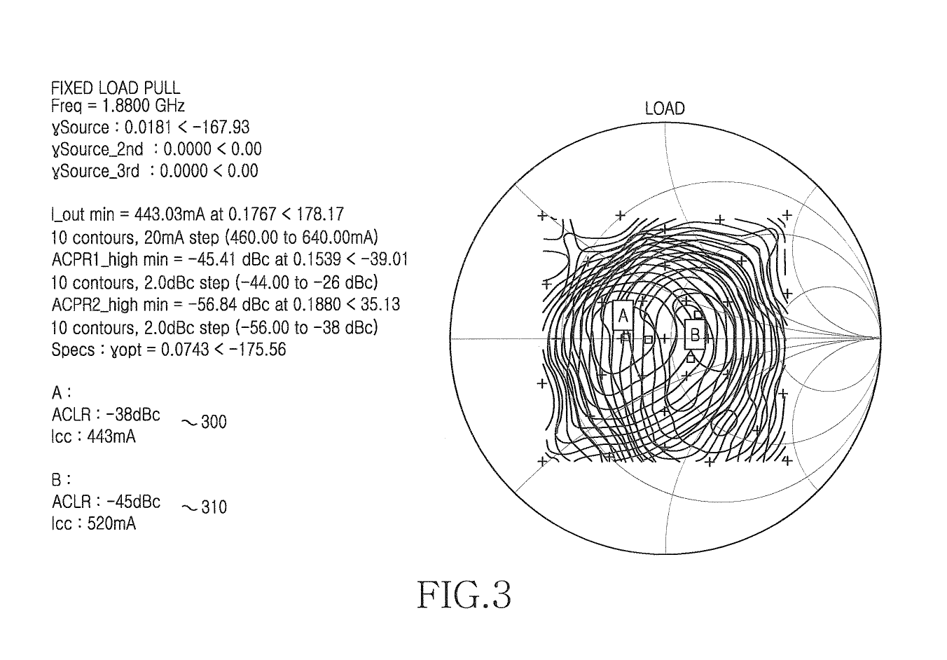

The matching module 112 matches a signal provided from the PAM 114 according to a matching value determined under control of the modem 120. That is, the matching module 112 matches an impedance using a matching value selected from at least two matching values under control of the modem 120. For example, when a supplied voltage of the PAM 114 is stable, the matching module 112 matches the impedance using a matching value selected such that a load of the PAM 114 is located at a point A 300 of FIG. 3 under control of the modem 120. As another example, when a supplied voltage of the PAM 114 is unstable, the matching module 112 matches the impedance using a matching value selected such that a load of the PAM 114 is located at a point B 310 of FIG. 3 under control of the modem 120. Here, FIG. 3 is a Smith chart illustrating points for moving a load of the PAM 114 under an environment where an output voltage is approximately 28.0 dBm in a band of 1880 MHz. As shown in FIG. 3, point A 300 represents a point where the Adjacent Channel Power Rejection (ACLR) is −38 dBC and the current consumption is approximately 443 mA. Likewise, point B 310 represents a point where the ACLR is −45 dBC and the current consumption is approximately 520 mA.

The PAM 114 amplifies and outputs power of a transmission signal provided from the RF processing module 118.

The voltage measuring module 116 determines a supplied voltage of the PAM 114.

The RF processing module 118 converts a baseband signal provided from the modem 120 into an RF signal and outputs the RF signal to the PAM 114.

The modem 120 modulates and encodes a transmission signal to transmit the same to the RF processing module 118. At this point, the modem 120 controls the matching module 112 to adaptively select a matching value depending on a supplied voltage of the PAM 114 provided from the voltage measuring module 116. For example, when a supplied voltage of the PAM 114 is greater than a reference voltage, the modem 120 recognizes that the supplied voltage is stable. In this case, the modem 120 controls the matching modem 112 to select a matching value such that current consumption is minimized. As another example, when a supplied voltage of the PAM 114 is smaller than the reference voltage, the modem 120 recognizes that the supplied voltage is unstable. In this case, the modem 120 controls the matching module 112 to select a matching value that increases linearity of the PAM 114.

The reception module 130 processes a reception signal provided from the duplexer 100.

In the above embodiments, the modem 120 controls a matching value of the matching module 112.

In an embodiment, a matching value of the matching module 112 may be controlled by the RF processing module 118.

Hereinafter, a method for changing a matching value depending on supplied power in the mobile terminal is described.

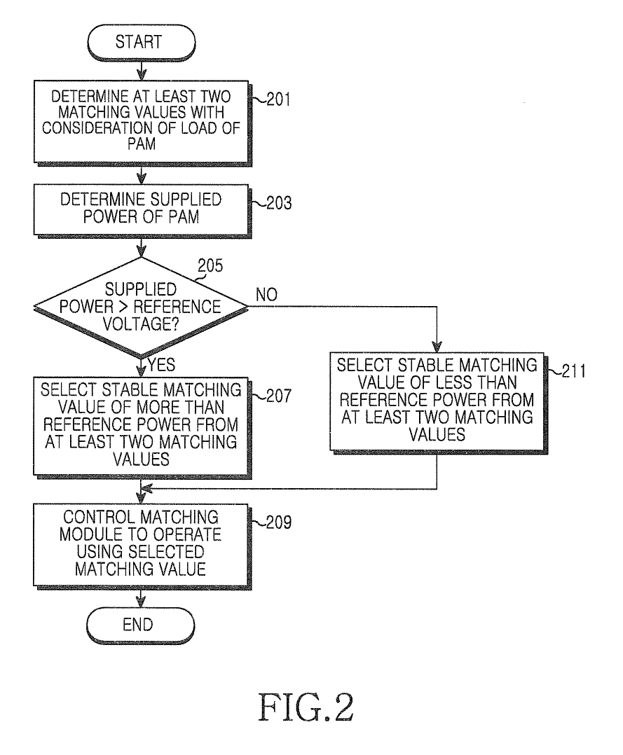

FIG. 2 is a flowchart illustrating a procedure for changing a matching value depending on supplied power in a mobile terminal according to an embodiment of the present invention.

Referring to FIG. 2, the mobile terminal determines at least two matching values for moving a load of the PAM 114 in step 201. For example, the mobile terminal determines at least two matching values for moving a load of the PAM 114 to a point A 300 or a point B 310 of FIG. 3.

The mobile terminal determines the supplied power of the PAM 114 in step 203.

After determining the supplied power of the PAM 114, the mobile terminal proceeds to step 205 to determine whether the supplied power of the PAM 114 is stable by comparing the supplied power of the PAM 114 with a reference power.

When the supplied power is greater than the reference power, the mobile terminal recognizes that the supplied power is stable. Accordingly, the mobile terminal proceeds to step 207 to select a matching value that minimizes current consumption. For example, the mobile terminal selects a matching value for moving a load of the PAM 114 to the point A 300 of FIG. 3.

In contrast, when the supplied power is smaller than or equal to the reference power, the mobile terminal recognizes that the supplied power is unstable. Accordingly, the mobile terminal proceeds to step 211 to select a matching value that increases linearity of the PAM 114. For example, the mobile terminal selects a matching value for moving a load of the PAM 114 to the point B 310 of FIG. 3.

After selecting the matching value, the mobile terminal proceeds to step 209 to adaptively match to the load of the PAM 114 using the selected matching value. For example, the mobile terminal matches the impedance using the selected matching value.

After that, the mobile terminal ends the present algorithm.

As described above, a transmission end of a wireless communication system adaptively uses a matching value depending on a supplied voltage of a PAM, so that current consumption may be reduced when power supply is stably maintained. When the power supply is unstable, transmission performance degradation may be prevented by increasing linearity of the transmission end.

Although the invention has been shown and described with reference to certain exemplary embodiments thereof, it will be understood by those skilled in the art that various changes in form and details may be made therein without departing from the spirit and scope of the invention as defined by the appended claims and their equivalents. Therefore, the scope of the present invention should not be limited to the above-described embodiments but should be determined by not only the appended claims but also the equivalents thereof.

What is claimed is:

1. An apparatus operable to prevent transmission degradation in a mobile terminal, the apparatus comprising:
an antenna;
a Power Amplifier Module (PAM) configured to amplify a power of a transmission signal; and
a matching module located between the antenna and the PAM, the matching module configured to match an impedance of a signal whose power is amplified by the PAM using a matching value determined based on a supplied power magnitude of the PAM.

2. The apparatus of claim 1, wherein the matching module selects one of at least two matching values based on the supplied power magnitude of the PAM.

3. The apparatus of claim 1, further comprising a voltage measuring module configured to determine the supplied power magnitude of the PAM.

4. The apparatus of claim 1, further comprising a modem configured to control a matching value of the matching module based on the supplied power magnitude of the PAM.

5. The apparatus of claim 1, wherein when the supplied power magnitude of the PAM is greater than a reference power under an environment where an output voltage is approximately 28.0 dBm in a band of 1880 MHz, the matching module matches an impedance of a signal whose power is amplified by the PAM using a matching value that moves a load of the PAM to a point where an Adjacent Channel Power Rejection (ACLR) is −38 dBC and a current consumption is 443 mA.

6. The apparatus of claim 1, wherein when the supplied power magnitude of the PAM is smaller than a reference power under an environment where an output voltage is approximately 28.0 dBm in a band of 1880 MHz, the matching module matches an impedance of a signal whose power is amplified by the PAM using a matching value that moves a load of the PAM to a point where an Adjacent Channel Power Rejection (ACLR) is −45 dBC and a current consumption is 520 mA.

7. A method for preventing transmission degradation in a mobile terminal, the method comprising:
determining a magnitude of supplied power of a Power Amplifier Module (PAM);
determining a matching value using the magnitude of the supplied power of the PAM; and
matching an impedance of a signal whose power is amplified by the PAM using, the matching value.

8. The method of claim 7, wherein the determining of the matching value comprises:
determining at least two matching values; and
selecting one of the at least two matching values based on the supplied power magnitude of the PAM.

9. The method of claim 7, wherein the determining of the matching value comprises, when a supplied power magnitude of the PAM is greater than a reference power under an environment where an output voltage is approximately 28.0 dBm in a band of 1880 MHz, selecting a matching value that moves a load of the PAM to a point where an Adjacent Channel Power Rejection (ACLR) is −38 dBC and a current consumption is 443 mA.

10. The method of claim 7, wherein the determining of the matching value comprises, when a supplied power magnitude of the PAM is smaller than a reference power under an environment where an output voltage is approximately 28.0 dBm in a band of 1880 MHz, selecting a matching value that moves a load of the PAM to a point where an Adjacent Channel Power Rejection (ACLR) is −45 dBC and a current consumption is 520 mA.

11. The method of claim 7, further comprising:
controlling the matching value based on the supplied power magnitude of the PAM.

12. A mobile terminal operable to prevent transmission degradation, the mobile terminal comprising:
an antenna;
a reception module; and
a transmission module, comprising:
a Power Amplifier Module (PAM) configured to amplify a power of a transmission signal; and
a matching module located between the antenna and the PAM, the matching module configured to match an impedance of a signal whose power is amplified by the PAM using a matching value determined based on a supplied power magnitude of the PAM.

13. The mobile terminal of claim 12, wherein the matching module selects one of at least two matching values based on the supplied power magnitude of the PAM.

14. The mobile terminal of claim 12, the transmission module further comprising a voltage measuring module configured to determine the supplied power magnitude of the PAM.

15. The mobile terminal of claim 12, the transmission module further comprising a modem configured to control a matching value of the matching module depending on the supplied power magnitude of the PAM.

16. The mobile terminal of claim 12, wherein when the supplied power magnitude of the PAM is greater than a reference power under an environment where an output voltage is approximately 28.0 dBm in a band of 1880 MHz, the matching module matches an impedance of a signal whose power is amplified by the PAM using a matching value that moves a load of the PAM to a point where an Adjacent Channel Power Rejection (ACLR) is −38 dBC and a current consumption is 443 mA.

17. The mobile terminal of claim 12, wherein when the supplied power magnitude of the PAM is smaller than a reference power under an environment where an output voltage is approximately 28.0 dBm in a band of 1880 MHz, the matching module matches an impedance of a signal whose power is amplified by the PAM using a matching value that moves a load of the PAM to a point where an Adjacent Channel Power Rejection (ACLR) is −45 dBC and a current consumption is 520 mA.

18. The mobile terminal of claim 12, further comprising a duplexer configured to separate signals of the transmission module and the reception module.

19. The mobile terminal of claim 12, the transmission module further comprising a Radio Frequency (RF) processing module configured to output the transmission signal to the PAM.

20. The mobile terminal of claim 12, wherein the mobile terminal is one of a wireless Personal Computer (PC), a mobile communication terminal, a Personal Digital Assistant (PDA), a smart phone, an International Mobile Telecommunication-2000 (IMT-2000) terminal, a Wideband Code Division Multiple Access (WCDMA) terminal, and a Universal Mobile Telecommunication Service (UMTS) terminal.
